(19) United States
(12) Patent Application Publication
(10) Pub. No.: US 2013/0308273 A1
(43) Pub. Date: Nov. 21, 2013

(54) LASER SINTERED MATCHING SET RADIATORS

(71) Applicants: Leo Gard, Sherman Oaks, CA (US); Karl Wefers, Simi Valley, CA (US)

(72) Inventors: Leo Gard, Sherman Oaks, CA (US); Karl Wefers, Simi Valley, CA (US)

(73) Assignee: HAMILTON SUNDSTRAND SPACE SYSTEMS INTERNATIONAL, Windsor Locks, CT (US)

(21) Appl. No.: 13/476,455

(22) Filed: May 21, 2012

(51) Int. Cl. H05K 7/20; B21D 53/02; B23P 11/00; B23K 26/20

(52) U.S. Cl. 361/704; 219/121.66; 29/890.03; 29/428

(57) ABSTRACT

A thermal management system for use in a vacuum is provided including a heat generation device and a heat dissipation device. A laser sintered first heat transfer panel is mounted to a surface of the heat generation device and a laser sintered second heat transfer panel is mounted to a surface of the heat dissipation device. The first and second heat transfer panels are positioned between the heat generation device and the heat dissipation device. A portion of the first heat transfer panel and a portion of the second heat transfer panel are interposed.

### BACKGROUND OF THE INVENTION

Exemplary embodiments of this invention generally relate to thermal management of electronics and, more particularly, to thermal management of electronics in space applications.

Operation of electronic components causes generation of heat that must be dissipated by some type of thermal management system. Without such a system, overheating may affect the performance or even cause failure of the electronic components. The most common forms of heat transfer include conduction, convection, and radiation. However, when an electronic component is located in a vacuum and no air is present, such as in space for example, only radiative heat transfer can occur.

Conventional thermal management systems have used adjacent radiator panels to transfer heat within a vacuum. To effectively transfer heat through radiation, adjacent radiator panels must be closely positioned so that the heat emitted by a first radiator panel is absorbed by a second radiator panel. Radiator panels were previously manufactured by tin milling or machining a solid piece of metal to a desired shape. Such methods are expensive and result in excessive material waste. In addition, the tolerances of the radiator panels manufactured using such methods are limited by the machinery used. Consequently, the spacing between adjacent radiator panels is larger than desired in some applications.

### BRIEF DESCRIPTION OF THE INVENTION

According to one embodiment of the invention, a thermal management system for use in a vacuum is provided including a heat generation device and a heat dissipation device. A laser sintered first heat transfer panel is mounted to a surface of the heat generation device and a laser sintered second heat transfer panel is mounted to a surface of the heat dissipation device. The first and second heat transfer panels are positioned between the heat generation device and the heat dissipation device. A portion of the first heat transfer panel and a portion of the second heat transfer panel are interposed.

According to an alternate embodiment of the invention, a method of forming a thermal management system for use in a vacuum is provided including creating a three dimensional computer model of a first heat transfer panel and a second heat transfer panel. A powder is laser sintered to form a first heat transfer panel and a second heat transfer panel. The first heat transfer panel is mounted to a surface of a heat generation device and the second heat transfer panel is mounted to a surface of a heat dissipation device. A portion of the first heat transfer panel and a portion of the second heat transfer panel are interposed.

### BRIEF DESCRIPTION OF THE DRAWINGS

The subject matter, which is regarded as the invention, is particularly pointed out and distinctly claimed in the claims at the conclusion of the specification. The foregoing and other features, and advantages of the invention are apparent from the following detailed description taken in conjunction with the accompanying drawings in which:

FIG. 1 is an exemplary thermal management system according to an embodiment of the invention; and

FIG. 2 is an exemplary method of forming a thermal management system according to an embodiment of the invention.

The detailed description explains embodiments of the invention, together with advantages and features, by way of example with reference to the drawings.

### DETAILED DESCRIPTION OF THE INVENTION

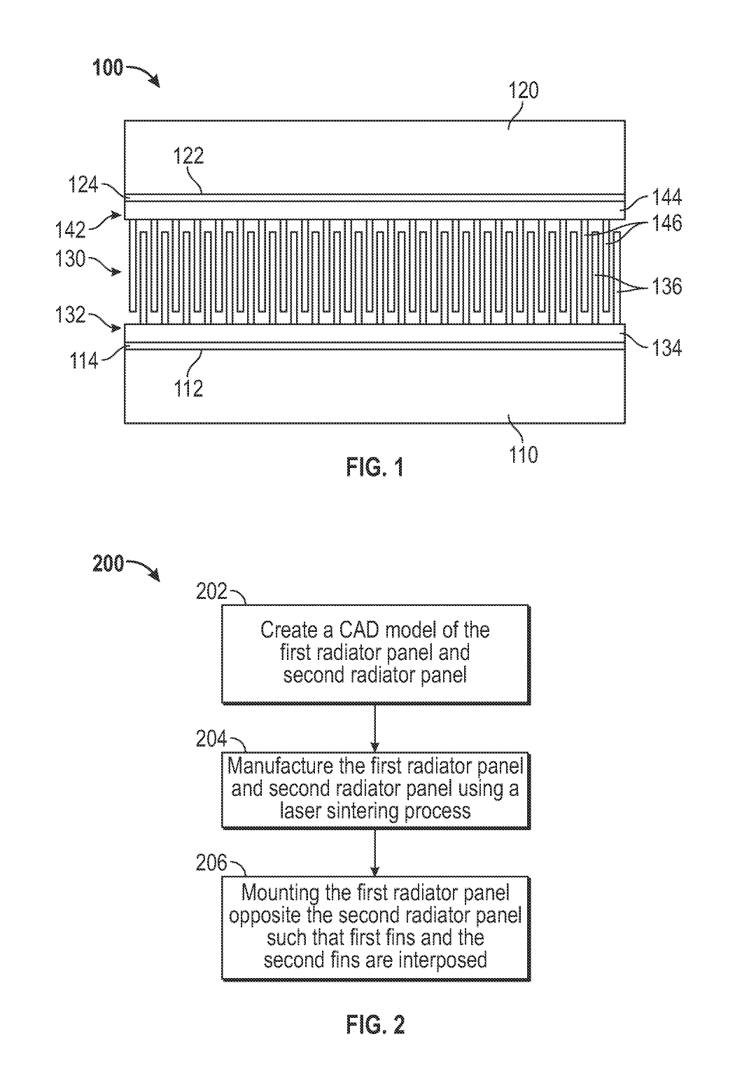

Referring now to FIG. 1, a thermal management system 100 for use in a vacuum, such as in space for example, is illustrated. The thermal management system 100 may be used to transfer heat to or from an electronic box 110. The electronic box 110 houses a plurality of electrical components, such as printed circuit boards, transistors, wiring, and other known electronics that generate heat when operated. A temperature control system 120 is located adjacent the electronic box 110 such that a surface 122 of the temperature control system 120 faces a surface 112 of the electronic box 110. In one embodiment, the temperature control system 120 removes the heat generated by the electrical components from the area surrounding the electronic box 110. Of course, depending on the context, the temperature control system 120 could provide heat to the electrical components in the electronic box 110. The temperature control system 120 may be referred to as a heat dissipation device and the electronic box 110 may be referred to as a heat generation device when the temperature control system 120 is dissipating heat generated by the electronic box 110. Conversely, when the temperature control system 120 is providing heat to the electronic box 110 the temperature control system 120 may be referred to as a heat generation device and the electronic box 110 may be referred to as a heat dissipation device.

The surface 122 of the temperature control system 120 may be generally the same size, or alternately may be a different size as the surface 112 of the electronic box 110.

Positioned between the temperature control system 120 and the electronic box 110 is a thermal radiation system 130. In one embodiment, the thermal radiation system 130 includes a first radiator panel 132 and a second adjacent radiator panel 142. The first radiator panel 132 includes a first base 134 and a plurality of uniform first fins 136 that extend generally perpendicularly from the first base 134. Similarly, the second radiator panel 142 includes a second base 144 and a plurality of uniform second fins 146 that extend generally perpendicular from the second base 144. To improve the efficiency of the thermal management system 100, the first base 134 and the second base 144 may be made from materials that maximize thermal conductivity, such as aluminum for example. In one embodiment, the first base 134 of the first radiator panel 132 is generally the same size as surface 112 of the electronic box 110 and the second base 144 of the second radiator panel 142 is generally the same size as surface 122 of the temperature control system 120. In an alternate embodiment, the first base 134 and the second base 144 may be larger or smaller than surfaces 112 and 122 respectively. The first base 134 is mounted to the surface 112 of the electronic box 110 with a first connector 114. In one embodiment, if electrical components are stored within only a portion of the electronic box 110, the first base 132 may be mounted to the portion of surface 112 adjacent the electronic components. The second base 144 is mounted to the surface 122 of the temperature control system 120 with a second connector 124. In one embodiment, the second base 144 is mounted to the portion of surface 122 generally opposite the first radiator panel 132. Exemplary connectors 114 and 124 used to attach the first and second radiator panels 132, 142 to surfaces 112 and 122 respectively may include fasteners, brazes, adhesive, or any other means known to a person skilled in the art.

In the illustrated configuration, the first fins 136 extend from the electronic box 110 in the direction of the temperature control system 120 and the second fins 146 extend from the temperature control system 120 in the direction of the electronic box 110, adjacent the plurality of first fins 136. In one embodiment, the first radiator panel 132 and the second radiator panel 142 are mounted such that the plurality of first fins 136 and second fins 146 are interposed or alternating. In other words, a second fin 146 is positioned between adjacent first fins 136 and a first fin 136 is positioned between adjacent second fins 146. In one embodiment, the first radiator panel 132 and the second radiator panel 142 are identical, and the spacing between adjacent fins 136, 146 is uniform along the length of the first and second radiator panels 132, 142. The distance of the spacing between adjacent fins will vary depending on the application of the thermal management system 100.

By mounting the first radiator panel 132 to the electronic box 110, heat generated within the electronic box 110 will conduct through the first connector 114 to the base 134 and fins 136 of the first radiator panel. The heat is emitted as electromagnetic radiation from the surface of the first radiator panel 132 to the surrounding area. The fins 146 of the second radiator panel 142, positioned between the fins 136 of the first radiator panel 132, absorb the radiant energy released by the first radiator panel 132. The energy absorbed by the fins 146 conducts through the second radiator panel 142 and the connector 124 to the temperature control system 120 where the heat is dissipated. This transfer of heat to the temperature control system 120 allows the second fins 146 to continually absorb the energy radiated by the fins 136 of the first radiator panel 132, thereby cooling the electronics box 110. Alternately, if the electronic box 110 must stay above a minimum temperature, the thermal management system 100 may be used to transfer heat to the electronic box 110. Heat generated by temperature control system 120 will conduct through connector 124 to the base 144 and fins 146 of the second radiator panel 142. The adjacent fins 136 of the first radiator panel 132 will absorb that heat radiating from the second radiator panel 142. This heat will conduct through the first radiator panel 132 and connector 114 to the electronic box 110.

Referring now to FIG. 2, a method 200 of forming a thermal management system 100 is illustrated. In block 202, a three-dimensional computer model, such as a CAD model for example, of the first radiator panel 132 and the second radiator panel 142 is created. The data from such a CAD file is then uploaded to a sinter machine. The laser of the sinter machine draws the cross section of the image from the CAD file in a layer of powder. The laser causes the powder to heat and fuse together, creating a solid mass having the cross section of the first radiator panel 132 and the second radiator panel 142. In block 204, continuous layers of powder are added to the surface of the cross section until the first radiator panel 132 and the second radiator panel 142 are complete. The first radiator panel 132 and the second radiator panel 142 may be manufactured during a single laser sintering process or during two separate laser sintering processes. In block 206, the first radiator panel 132 is mounted to the electronic box 110 and the second radiator panel is mounted to the temperature control system 120 such that the plurality of first fins 136 and the plurality of second fins 146 are interposed.

By laser sintering the first radiator panel 132 and the second radiator panel 142, the minimum spacing required between adjacent fins for manufacturing is reduced. In addition, the efficiency of the manufacturing process is improved because both the first radiator panel 132 and the second radiator panel 142 may be manufactured at the same time. Also, laser sintered radiator panels have a reduced cost because excess material is not wasted during the manufacturing process.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. A thermal management system for use in a vacuum comprising:
a heat generation device;
a heat dissipation device;
an laser sintered first heat transfer panel mounted to a surface of the heat generation device between the heat generation device and the heat dissipation device; and
an laser sintered second heat transfer panel mounted to a surface of the heat dissipation device between the heat dissipation device and the heat generation device, wherein a portion of the first heat transfer panel and a portion of the second heat transfer panel are interposed.

2. The thermal management system according to claim 1, wherein the laser sintered first and second heat transfer panels are radiator panels.

3. The thermal management system according to claim 1, wherein the heat generation device includes at least one electronic component.

4. The thermal management system according to claim 1, wherein the heat dissipation device includes a liquid cooling device.

5. The thermal management system according to claim 1, wherein a connector is used to mount the first heat transfer panel to the surface of the heat generation device and the second heat transfer panel to the surface of the heat dissipation device.

6. The thermal management system according to claim 5, wherein the connector is a braze.

7. The thermal management system according to claim 1, wherein the first heat transfer panel includes a first base and a plurality of first fins extending generally perpendicularly from the first base and the second heat transfer panel includes a second base and a plurality of second fins extending generally perpendicularly from the second base.

8. The thermal management system according to claim 7, wherein the plurality of first fins of the first heat transfer device and the plurality of second fins of the second heat transfer device are interposed.

9. The thermal management system according to claim 1, wherein the first heat transfer device is mounted to the surface of the heat generation device and the second heat transfer device is mounted to the surface of the heat dissipation device opposite the first heat transfer device.

10. The thermal management system according to claim 1, wherein the first heat transfer device and the second heat transfer device are identical.

11. The thermal management system according to claim 10, wherein the first heat transfer device and the second heat transfer device are mounted such that the plurality of first fins and the plurality of second fins are equally spaced.

12. A method of forming a thermal management system for use in a vacuum comprising:
creating an three dimensional model of a first heat transfer panel;
laser sintering a powder to form a first heat transfer panel and a second heat transfer panel;
mounting the first heat transfer panel to a surface of a heat generation device; and mounting the second heat transfer panel to a surface of a heat dissipation device such that a portion of the first heat transfer panel and a portion of the second heat transfer panel are interposed.

13. The method according to claim 12, wherein the first heat transfer panel and the second heat transfer panel are radiator panels.

14. The method according to claim 12, wherein the first heat transfer panel and the second heat transfer device are formed at the same time.

15. The method according to claim 12, wherein the first heat transfer panel and the second heat transfer panel are identical.

16. The method according to claim 12, wherein the first heat transfer panel includes a first base and a plurality of first fins and the second heat transfer panel includes a second base and a plurality of second fins.

17. The method according to claim 16, wherein the plurality of first fins and the plurality of second fins are interposed.

18. The method according to claim 16, wherein the first heat transfer panel and the second heat transfer panel are mounted such that the plurality of first fins and the plurality of second fins are equally spaced.

19. The method according to claim 12, wherein the first heat transfer panel is mounted to the surface of the heat generation device and the second heat transfer panel is mounted to the surface of the heat dissipation device opposite the first heat transfer panel.

20. The method according to claim 12, wherein a connector is used to mount the first heat transfer panel to the surface of the heat generation device and the second heat transfer panel to the surface of the heat dissipation device.
